(19) United States
(12) Patent Application Publication
(10) Pub. No.: US 2014/0077286 A1
(43) Pub. Date: Mar. 20, 2014

(54) FIELD-EFFECT TRANSISTOR

(71) Applicant: KABUSHIKI KAISHA TOSHIBA, Tokyo (JP)

(72) Inventor: Masahiko KUBO, Hyogo (JP)

(73) Assignee: KABUSHIKI KAISHA TOSHIBA, Tokyo (JP)

(21) Appl. No.: 14/016,274

(22) Filed: Sep. 3, 2013

(30) Foreign Application Priority Data
Sep. 19, 2012 (JP) 2012-206323

(51) Int. Cl. H01L 29/78

(52) U.S. Cl. CPC H01L 29/78
USPC 257/327

(57) ABSTRACT

According to one embodiment, a field-effect transistor is provided with a first conductivity-type first semiconductor layer, a source layer formed of a second conductivity-type semiconductor, a drain layer formed of a second conductivity-type semiconductor, and a gate electrode. The source layer is located on the first semiconductor layer. The drain layer is also located on the first semiconductor layer and is separated from the source layer. The gate electrode is located adjacent to the side wall of the drain layer which faces the source layer, and may also be located adjacent to the side wall of the source layer facing the drain layer, and on the first semiconductor layer with a gate insulating film formed therebetween. The upper surface of the gate electrode is recessed with respect to at least the upper surface of the drain layer.

### CROSS-REFERENCE TO RELATED APPLICATION

This application is based upon and claims the benefit of priority from Japanese Patent Application No. 2012-206323, filed Sep. 19, 2012, the entire contents of which are incorporated herein by reference.

### FIELD

Embodiments described herein relate generally to a field-effect transistor.

### BACKGROUND

In field-effect transistors that are used in tuners, radios, and the like, the on-state resistance needs to be low, the gate-to-source capacitance needs to be small, and the gate-to-drain capacitance needs to be small. One known approach for lowering the on state resistance is to shorten the channel length by narrowing the spacing between a drain layer and a source layer. However, if the channel length is shortened too much, a short channel effect causes a current to flow between a drain and a source, regardless of the gate voltage, i.e., the gate leaks. Therefore, there is a need for a field-effect transistor in which the on-state resistance is low and the short channel (gate leakage) effect is suppressed.

### DESCRIPTION OF THE DRAWINGS

FIG. 1 is a schematic cross-sectional view showing the main parts of the field-effect transistor of a first embodiment.

FIG. 2 shows the parasitic capacitance locations or regions of a field-effect transistor of a first embodiment.

FIG. 3 is a schematic cross-sectional view showing the field-effect transistor of the first embodiment demonstrating a portion of the manufacturing steps thereof.

FIG. 4 is a schematic cross-sectional view of the field-effect transistor of the first embodiment demonstrating the result of further manufacturing steps thereof.

FIG. 5 is a schematic cross-sectional view of the field-effect transistor of the first embodiment demonstrating the result of still further manufacturing steps thereof.

FIG. 6 is a schematic cross-sectional view showing of the field-effect transistor of the first embodiment demonstrating the result of yet further manufacturing steps thereof.

FIG. 7 is a schematic cross-sectional view showing the field-effect transistor of the first embodiment having been further processed nearer to its final configuration, which is shown in FIG. 1.

FIG. 8 is a schematic cross-sectional view showing the main parts of the field-effect transistor of a second embodiment.

### DETAILED DESCRIPTION

A field-effect transistor in which an on-state resistance is low and a short channel effect is suppressed is provided herein.

In general, according to one embodiment, the field-effect transistor of the present disclosure is provided with a first conductivity-type first semiconductor layer, a source layer comprising a second conductivity-type semiconductor layer, a drain layer comprising a second conductivity-type semiconductor, and a gate electrode. The drain and source layers are formed directly on the first conductivity type semiconductor layer, with a gap therebetween. A gate insulating film is formed over the source layer, drain layer, and the gap, such that the side walls of the source and drain layers forming the sides of the gap are also covered by the gate insulating layer. The gate electrode is located in the gap, the sides of which are located adjacent to the side walls of the source and drain layers, with the gate insulating layer disposed therebetween. The upper surface of the gate electrode does not extend the full height of the gap, i.e., the thickness of the gate electrode is such that the upper surface thereof is recessed within the gap between the source layer and drain layer.

The embodiments of the present disclosure will be explained with reference to the drawings. The drawings, which are used in the explanation of the embodiments, are schematic for facilitating the explanation, and the shape, size, size relation, etc., of each element in the drawings, and the elements are not necessarily limited to those shown in the drawings in actual applications but can be appropriately changed where the effect of the present disclosure can still be obtained. In the following explanation, the first conductivity type is assumed as a p-type, and the second conductivity type is assumed as an n-type. However, these conductivity types can also be respectively their opposite conductivity types. As a semiconductor, silicon is explained as an example; however, compound semiconductors such as silicon carbide (SiC) and nitride semiconductor (GaN) can also be applied. As an insulating film, silicon oxide is explained as an example; however, other insulators such as silicon nitride, silicon oxynitride, and alumina can also be used. In case the n-type conductivity type is indicated by n⁺, n, and n⁻, the n-type dopant concentration is low in this order. As for the p-type, similarly, the p-type dopant concentration is low in order of p⁺, p, and p⁻.

### First Embodiment

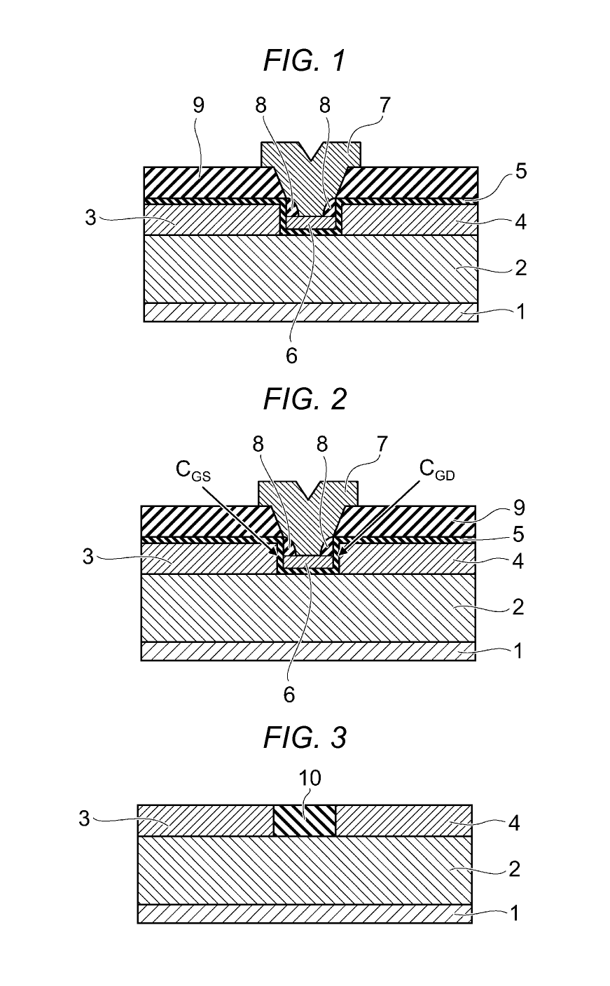

With reference to FIGS. 1 and 2, the field-effect transistor of a first embodiment of the present disclosure will be explained. FIG. 1 is a schematic cross-sectional view showing the main parts of the field-effect transistor of this embodiment. FIG. 2 shows the location of a parasitic capacitance of the field-effect transistor of this embodiment.

As shown in FIG. 1, the field-effect transistor of this embodiment is formed of a p⁺-type substrate 1, a p-type base layer 2 (a first conductivity-type first semiconductor layer), an n⁺-type source layer 3 (a source layer comprising a second conductivity-type semiconductor), an n⁺-type drain layer 4 (a drain layer comprising a second conductivity-type semiconductor), a gate insulating film 5, a gate electrode 6, a gate metal 7, an insulating film 8, and an interlayer dielectric 9. The p⁺-type substrate 1, the p-type base layer 2, the n⁺-type source layer 3, and the n⁺-type drain layer 4 are semiconductors, for example, silicon. The n-type impurities, for example, are phosphorus (P), and the p-type impurities, for example, are boron (B).

The p-type dopant concentration of the p⁺-type substrate 1, for example, is 1×10²⁰/cm³ or higher. The p-type base layer 2 is installed on the p⁺-type substrate. The p-type dopant concentration of the p-type base layer 2, for example, is 1×10¹⁵/cm³ to 1×10¹⁶/cm³. The n⁺-type source layer 3 is installed on the upper surface opposite to the p⁺-type substrate of the p-type base layer 2. On the lower surface of the p-type base layer 2, there is the p⁺-type substrate 1. The n⁺-type drain layer 4 is formed on the upper surface of the p-type base layer and is separated from the n⁺-type source layer 3 also formed on the p type base 2 along the span of the upper surface of the p type base layer 2. The n-type dopant concentration of the n⁺-type source layer 3 and the n⁺-type drain layer 4 is, for example, 1×10²⁰/cm³ to 1×10²¹/cm³.

The gate insulating film is formed as a blanket film over the source 3 and drain 4 layers, and thus is formed on the side wall of the n⁺-type source layer 3 facing the n⁺-type drain layer 4, on the upper surface of the p-type base layer 2 extending in the space between the source 3 and drain 14 layers, and on the side wall of the n⁺-type drain layer 4 facing the n⁺-type source layer 3. The gate insulating film, for example, is silicon dioxide (SiO₂). Instead of silicon oxide, silicon nitride (SiN) or silicon oxynitride (SiON) can also be used.

The gate electrode 6 is formed over the gate insulating film 5 in the space between the source 3 and drain 4 layers, and extends against and is bounded by the side wall of the n⁺-type source layer 3, the upper surface of the p-type base layer 2, and the side wall of the n⁺-type drain layer 4. The gate electrode 6, for example, may be a metal with a high melting point. For example, molybdenum (Mo), molybdenum silicide, titanium (Ti), tungsten (W), etc. may be used. However, without being limited to these examples, the gate electrode 6 may also be conductive, i.e., doped silicon, such as doped polysilicon. The gate electrode 6 is thinly formed so that the upper surface of the gate electrode 6 located opposite to the p-type base layer 2 is maintained within the recess or gap formed between the n⁺-type source layer 3 and the upper surface opposite to the n⁺-type drain layer 4.

The gate metal 7 is formed so that the gate metal is electrically connected to the upper, exposed in the recess, surface of the gate electrode 6. The gate metal 7 contacts and is electrically connected to the upper surface of the gate electrode 6 over a portion of the upper surface of the gate electrode 6. The gate metal 7 is formed of a metal and may be, for example, aluminum or copper materials which are commonly used as an electric wiring layer in semiconductive devices. With the installation of the gate metal 7 along the upper surface of the gate electrode 6, the gate resistance of the gate electrode 6 is lowered. With the installation of the gate metal 7 on the gate electrode 6, even if the gate electrode 6 is formed of conductive silicon, such as doped polysilicon, the gate resistance is lowered.

The insulating film 8 is formed to be positioned between the gate metal 7 contacting the upper surface of the gate electrode 6 and the adjacent n⁺-type source layer 3 and between the gate metal 7 contacting the upper surface of the gate electrode 6 and the adjacent n⁺-type drain layer 4. The insulating film 8 is, for example, the same silicon oxide as the silicon oxide of the gate insulating film 5. However, the gate insulating film 8 is not limited to a silicon oxide material but can also be an insulating film with a dielectric constant lower than the dielectric constant of the gate insulating film 5. For example, the insulating film 8 may comprise one of fluorine-doped silicon oxide (SiOF), carbon-doped silicon oxide (Sic), boron nitride (BN), polyimide, and an organic polymer.

The interlayer dielectric 9 is located on the n⁺-type source layer 3 and the n⁺-type drain layer 4. The interlayer dielectric 9 may be, for example, silicon oxide; however, silicon nitride or silicon oxynitride can also be used. An opening part is installed in the interlayer dielectric 9. The gate metal 7 is electrically connected to the gate electrode 6 through an opening extending through the interlayer dielectric, which opening is, in this embodiment, aligned with the sides of the gate electrode.

The gate electrode 6 extends from the gate area to agate pad, which is not shown in the figure. The n⁺-type source layer 3 is electrically connected to a source electrode, which is not shown in the figure. In addition, the n⁺-type drain layer 4 is electrically connected to a drain electrode, which is not shown in the figure.

Next, the operation and the characteristics of the field-effect transistor of this embodiment will be explained. If a positive voltage higher than the threshold of the source electrode is applied to the gate electrode 6, a channel layer is formed on the surface of the p-type base layer 2 underlying the gate insulating film 5. Here, if the positive voltage to the source electrode is applied to the drain electrode, electrons flow from the n⁺-type source layer 3 to the n⁺-type drain layer 4 via the channel layer in the p-type base layer 2. As a result, a current flows to the source electrode from the drain electrode, setting the field-effect transistor to an on-state.

If the voltage applied to the gate electrode is lower than the threshold, the channel layer in the p-type base layer 2 extending between the source 3 and drain 4 is lost, setting the field-effect transistor to an off-state. In the off-state, a depletion layer extends into the p-type base layer 2 from a p-n junction of the n⁺-type drain layer 4 and the p-type base layer 2 caused by the increase of the drain-source voltage.

In the field-effect transistor of this embodiment, since the n⁺-type drain layer 4 and the gate electrode 6 are formed on the upper surface of the p-type base layer 2, the lower surface of the n⁺-type drain layer 4 in contact with the p-type base layer 2 is not present at the portion of the p type base layer 2 underlying the gate electrode 6. For this reason, the p-n junction surface of the n⁺-type drain layer 4 and the p-type base layer 2 does not have a corner part with a sharp corner. Therefore, a local electric field concentration on the p-n junction of the n⁺-type drain layer 4 and the p-type base layer 2 is suppressed. As a result, leakage current resistance between the n⁺-type drain layer 4 and the p-type base layer 2 is improved. In addition, the depletion layer extending into the p-type base layer 2 from the n⁺-type drain layer 4 cannot easily extend toward the n⁺-type source layer 3. For this reason, even when the channel length is shortened by narrowing the spacing between the n⁺-type source layer 3 and the n⁺-type drain layer 4, the short channel effect otherwise causing a leaky gate is difficult to generate. In other words, in the field-effect transistor of this embodiment, the on-state resistance is lowered while suppressing the short channel effect and attendant leakage current.

As shown in FIG. 2, in the power semiconductor device of this embodiment, a gate-to-source parasitic capacitance C_{GS} exists because of the gate insulating film 5 extending between the gate electrode 6 and the n⁺-type source layer 3. In addition, a gate-to-drain parasitic capacity C_{GD} exists because of the gate insulating film 5 extending between the gate electrode 6 and the n⁺-type drain layer 4. In the field-effect transistor of this embodiment, the upper surface of the gate electrode 6 is situated at the p-type base layer 2 side with respect to the upper surface of the n⁺-type source layer 3 and the upper surface of the n⁺-type drain layer 4, in other words, within the height of the gap or recess between them. For this reason, compared with a power semiconductor device in which the gate electrode 6 is formed so that the upper surface of the gate electrode 6 extends to about the same surface as the upper surface of the n⁺-type source layer 3 and the upper surface of the n⁺-type drain layer 4, the gate-to-source parasitic capacitance C_{GS} and the gate-to-drain parasitic capacitance C_{GD} are smaller in the power semiconductor device of this embodiment.

In addition, in this embodiment, since the gate metal 7 is installed on the gate electrode 6, a parasitic capacitance between the gate metal 7 and the n⁺-type source layer 3 and a parasitic capacitance between the gate metal 7 and the n⁺-type drain layer 4 are respectively added to the gate-to-source parasitic capacitance C_{GS} and the gate-to-drain parasitic capacitance C_{GD}.

However, since the insulating film 8 exists in series with the gate insulating film 5 between the gate metal 7 and the n⁺-type source layer 3, the parasitic capacity between the gate metal 7 and the n⁺-type source layer 3 is much smaller than the parasitic capacitance between the gate electrode 6 and the n⁺-type source layer 3. Similarly, the insulating film 8 exists in series with the gate insulating film 5 between the gate metal 7 and the n⁺-type drain layer 4, so the parasitic capacitance between the gate metal 7 and n⁺-type drain layer 4 is much smaller than the parasitic capacitance between the gate electrode 6 and n⁺-type drain layer 4. Therefore, the parasitic capacitance between the gate metal 7 and the n⁺-type source layer 3 and the parasitic capacitance between the gate metal 7 and the n⁺-type drain layer 4 are almost negligible. This effect can be obtained by increasing the thickness in the horizontal direction of the insulating film 8 so that the thickness is greater than the thickness of the insulating film 5 or by setting the dielectric constant of the insulating film 8 so that the dielectric constant is lower than the dielectric constant of the gate insulating film 5, even though the thickness in the horizontal (width of the gap) direction is small.

Moreover, in the field-effect transistor of this embodiment, the gate metal 7 is located on the gate electrode 6; however, this transistor is not limited to this configuration. As long as the gate electrode 6 is formed of a metallic material with low resistance, the gate resistance can be maintained to be low, even without installing the gate metal 7. In that case, where no gate metal exists, the parasitic capacitance between the gate metal 7 and the n⁺-type source layer 3 and the parasitic capacitance between the gate metal 7 and the n⁺-type drain layer 4 are not significant.

Therefore, in the power semiconductor device of this embodiment, the upper surface of the gate electrode 6 is situated at the p-type base layer 2 side with respect to the upper surface of the n⁺-type source layer 3 and the upper surface of the n⁺-type drain layer 4, thus reducing the gate-to-source parasitic capacitance C_{GS} and the gate-to-drain parasitic capacitance C_{GD}. As a result, the power gain of the power semiconductor device is improved. For example, a power gain for an input signal of 1 GHz is improved by 5%.

Next, the method for manufacturing the field-effect transistor of this embodiment will be explained with reference to FIGS. 3 to 7. As shown in FIG. 3, the p-type base layer 2 is prepared on the p⁺-type semiconductor substrate 1. A mask 10 having a prescribed pattern is formed on the upper surface of the p-type base layer 2. The mask 10, for example, is silicon oxide.

Next, an n-type silicon is selectively, epitaxially grown on the upper surface of the p-type base layer 2 exposed from the mask 10 by a Chemical Vapor Deposition (CVD) method. The mask is then removed, so that the n⁺-type source layer 3 and the n⁺-type drain layer 4 are separated from each other by a gap, and are formed on the upper surface of the p-type base layer 2 with the gap therebetween.

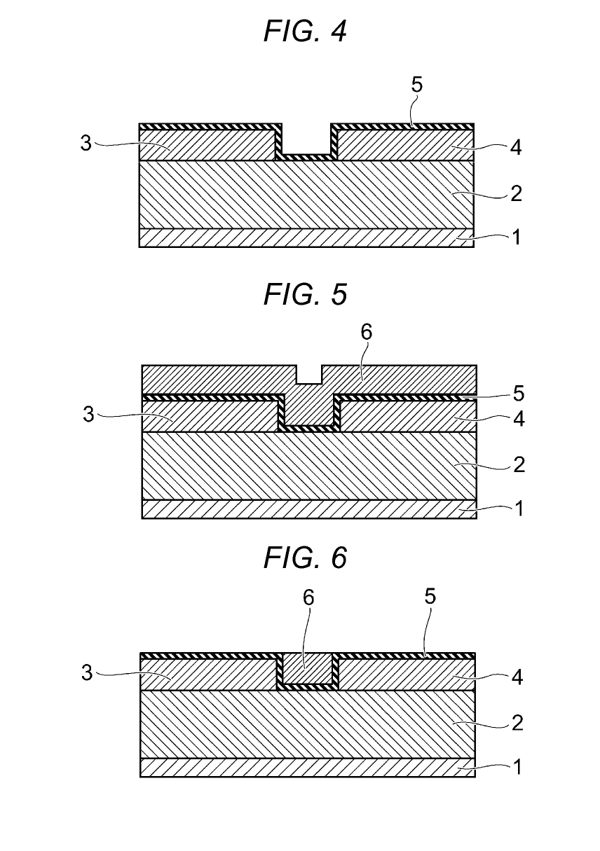

Next, as shown in FIG. 4, a silicon oxide gate insulator film 5 for example, is formed by a CVD method or by thermal oxidation so that the n⁺-type source layer 3, the p-type base layer 2, and the n⁺-type source drain layer 4 are covered. As a result, the gate insulating film 5 is formed on the side wall of the n⁺-type source layer 3 facing the n⁺-type drain layer 4, on the upper surface of the p-type base layer 2, and on the side wall of the n⁺-type drain layer 4 facing the n⁺-type source layer 3, as well as over the upper surfaces of the n⁺-type source layer 3 and the n⁺-type drain layer 4.

Next, as shown in FIG. 5, for example, molybdenum as a metal with a high melting point is deposited over the gate insulating film 5 on the n⁺-type source layer 3, on the p-type base layer 2, and on the n⁺-type drain layer 4.

As shown in FIG. 6, for example, the molybdenum is flattened by a CMP method (Chemical Mechanical Polishing) until the gate insulating film 5 is exposed. As a result, the gate electrode 6 is located over the gate insulating film 5 on the side wall of the n⁺-type source layer 3, on the upper surface of the p-type base layer 2, and on the side wall of the n⁺-type drain layer 4. The upper surface of the gate electrode 6 is almost on the same surface as the upper surface of the n⁺-type source layer 3 and the upper surface of the n⁺-type drain layer 4.

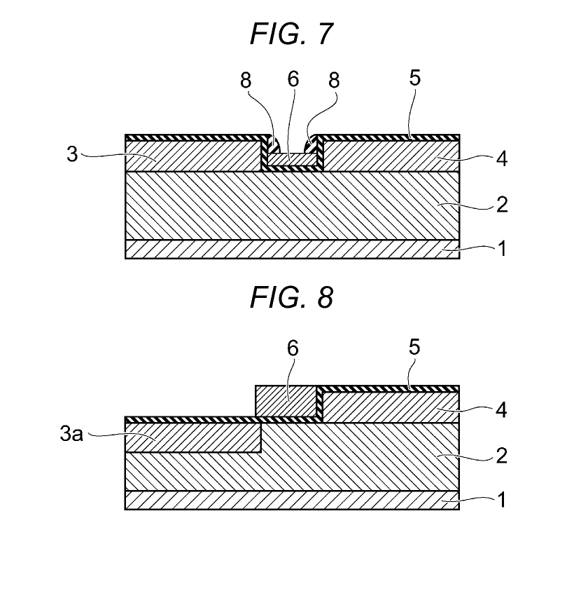

Next, as shown in FIG. 7, the gate electrode 6 is, for example, etched by the RIE method (Reactive Ion Etching), etc. so that the upper surface of the gate electrode 6 is positioned inwardly of the upper surface of the n⁺-type source layer 3 and the upper surface of the n⁺-type drain layer 4. Then, at both sides of the upper surface of the gate electrode 6, the insulating film 8 is formed over the gate insulating film 5 on the side wall of the n⁺-type source layer 3 and on the side wall of the n⁺-type drain layer 4, and over a portion of the gate electrode 6. For example, silicon oxide is formed on the gate electrode 6 between the n⁺-type source layer 3 and the n⁺-type drain layer 4, and an opening to expose the upper surface of the gate electrode 6 is then formed in the insulating film 8 by RIE method, etc., thus forming the insulating film 8 as shown in FIG. 7.

Next, the interlayer dielectric 9 as shown in FIG. 1 is formed on the n⁺-type source layer 3 and the n⁺-type drain layer 4. In the interlayer dielectric 9, an opening communicating with the upper surface of the gate electrode 6 is formed as is shown in FIG. 1, and the gate metal 7 is formed on the interlayer dielectric 9 so that the gate metal has a prescribed pattern, and the gate metal 7 is electrically connected to the gate electrode 6 via the opening of the interlayer dielectric 9. Therefore, the power semiconductor device of this embodiment shown in FIG. 1 can be formed.

### Second Embodiment

The field-effect transistor of a second embodiment will be explained with reference to FIG. 8. FIG. 8 is a schematic cross-sectional view showing the main parts of the field-effect transistor of the second embodiment. The same reference numbers or symbols are rendered to parts with the same configurations as the configurations explained in the first embodiment, and their repetitive explanation is omitted. The difference from the first embodiment will be mainly explained.

In the field-effect transistor of this embodiment, the n⁺-type source layer 3 is not formed on the upper surface of the p-type base layer 2 but is formed in the upper surface of the p-type base layer 2. In other words, the n⁺-type source layer 3 is formed so that this source layer is extended into the p-type base layer 2 from the upper surface of the p-type base layer 2. The n⁺-type source layer 3, for example, can be formed by forming the n⁺-type drain layer 4, the gate insulating film 5, and the gate electrode 6 in a prescribed shape on the p-type base layer 2 and then ion-implanting n-type impurities into the p-type base layer 2, using the gate electrode 6 as a mask.

The gate electrode 6 is formed so that the upper surface of the gate electrode 6 is situated on about the same surface as the upper surface of the n⁺-type drain layer 4. However, without being limited to this configuration, the upper surface of the gate electrode 6 may be positioned closer to the upper surface of the p-type base layer 2 or may also be embedded therein. In addition, the gate metal 7 and the interlayer dielectric 9 formed in the field-effect transistor of the first embodiment can be formed.

In the field-effect transistor of this embodiment, since the gate insulating film 5 sandwiched by the side wall of the n⁺-type source layer 3 and the gate electrode 6 does not exist, the gate-to-source parasitic capacitance C_{GS} due to this structure does not exist. For this reason, in the field-effect transistor of this embodiment, as compared with the field-effect transistor of the first embodiment, the gate-to-source capacitance C_{GS} can be significantly decreased.

Moreover, in the field-effect transistor of this embodiment, similar to the field-effect transistor of the first embodiment, the n⁺-type drain layer 4 is formed on the upper surface of the p-type base layer 2. For this reason, the lower surface of the n⁺-type drain layer 4 in contact with the p-type base layer 2 is not extended to the p-type base layer 2 side with respect to the gate insulating film 5 of the lower part of the gate electrode 6. As a result, the field effect concentration on a p-n junction of the n⁺-type drain layer 4 and the p-type base layer 2 is suppressed, improving the current leakage resistance between the n⁺-type drain layer 4 and the p-type base layer 2.

Furthermore, a depletion layer extending into the p-type base layer 2 from the n⁺-type drain layer 4 cannot easily extend toward the n⁺-type source layer 3. For this reason, even if the channel length is shortened by narrowing the spacing between the n⁺-type source layer 3 and the n⁺-type drain layer 4, a short channel effect is difficult to generate. In other words, in the field-effect transistor of this embodiment, the on-state resistance is lowered while suppressing the short channel effect.

In addition, in the field-effect transistor of this embodiment, the gate electrode 6 is located adjacent to the side wall of the n⁺-type drain layer 4 with the gate insulating film 5 therebetween. The structure of the gate electrode 6 is formed as follows. First, the n⁺-type drain layer 4 is formed on the surface of the p-type base layer 2 so that the drain layer forms a step on the p-type drain layer 2. Next, the insulating film 5 and the gate electrode 6 are sequentially formed on the p-type base layer and the n⁺-type drain layer.

Here, the thickness of the gate electrode 6 adjacent to the side wall of the n⁺-type drain layer 4 is greater than the thicknesses of the p-type base layer 2 and of the n⁺-type drain layer 4. For this reason, without using a mask, for example, the entire gate electrode 6 is etched anisotropic etching, such as the RIE method, thus forming the gate electrode 6 adjacent to only the side wall of the n⁺-type drain layer 4 as shown in FIG. 8. The width in the horizontal direction of the gate electrode 6 can be controlled by the film formation thickness of the gate electrode 6.

Therefore, according to the field-effect transistor of this embodiment, since a lithography step for forming a mask can be omitted, the production cost can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A field-effect transistor, comprising:
a first conductivity type base layer;
a second conductivity type source layer and a second conductivity type drain layer formed in contact with the base layer, having a gap therebetween;
the source and the drain layers having a predetermined thickness such that the upper surface of at least one of the source and the drain layers extends a predetermined distance from the first conductivity type layer such that a sidewall of at least one of the source layer and the drain layer extends from the surface of the first conductivity type layer; and
a gate electrode located adjacent to the sidewall, the upper surface of the gate electrode extending a smaller distance from the first conductivity type base layer than the upper surface of the at least one of the source layer or the drain layer extending from the first conductivity type layer.

2. The field-effect transistor of claim 1, wherein the source layer and the drain layer both extend from the surface of the first conductivity type layer such that the gap is formed as a recess therebetween in which the first conductivity type layer is exposed.

3. The field-effect transistor of claim 2, further including an insulating layer extending between the gate electrode and the adjacent surface of the drain layer and source layer.

4. The field-effect transistor of claim 3, further including an insulating layer formed on the gate electrode adjacent to the sides of the gap, with an opening therein through which the gate electrode upper surface is exposed.

5. The field-effect transistor of claim 4, wherein a second electrode extends through the opening in the insulating layer into contact with the gate electrode.

6. The field-effect transistor of claim 5, wherein the gate electrode is a doped semiconductor.

7. The field-effect transistor of claim 6, wherein the second electrode comprises a metal.

8. The field-effect transistor of claim 5, wherein the gate electrode comprises a metal, and the second electrode comprises a metal.

9. The field-effect transistor of claim 8, wherein the gate electrode metal and the second electrode are different metals.

10. The field-effect transistor of claim 5, wherein the distance between the second electrode and the portion of the source or the drain facing the gap is greater than the distance between the gate electrode and the portion of the source or the drain facing the gap.

11. The field-effect transistor of claim 4, further including
an interlayer dielectric located over the source layer and the drain layer, having an aperture therebetween overlying the gap; and
the second electrode extends over the interlayer dielectric and through the aperture in the aperture in the interlayer dielectric.

12. A field-effect transistor, comprising:
a first conductivity-type first semiconductor layer;
a source layer that is located on the first semiconductor layer and formed of a second conductivity-type semiconductor;
a drain layer that is located on the first semiconductor layer, is separated from the source layer, and is formed of a second conductivity-type semiconductor, such that the source and drain layers have facing sidewalls at the location of the separation; and
a gate electrode located on a gate insulating film formed on the facing side walls of the drain layer and the source layer and on the first semiconductor layer, wherein
the upper surface of the gate layer extending furthest from the first semiconductor is situated closer to the first conductivity type layer than are the upper surface of the source layer and the upper surface of the drain layer.

13. The field-effect transistor according to claim 12, further comprising:
a gate metal layer is formed the gate electrode; and
an insulating film is located on the gate electrode between the source layer and the gate metal and between the drain layer and the gate metal.

14. The field-effect transistor according to claim 13, wherein the dielectric constant of the insulating film is lower than the dielectric constant of the gate insulating film.

15. The field-effect transistor according to claim 14, wherein the insulating film is formed of one of fluorine-doped silicon oxide, carbon-doped silicon oxide, boron nitride, and an organic polymer.

16. A field-effect transistor, comprising:
a first conductivity-type first semiconductor layer;
a source layer formed of a second conductivity-type semiconductor installed so that the source layer is formed in a p-type base layer and extends inwardly of the upper surface of the first semiconductor layer;
a drain layer that is formed on the first semiconductor layer, and is spaced from the source layer and includes a side wall extending from the first semiconductor layer and facing the location of the source layer, the drain layer formed of the second conductivity type semiconductor; and
a gate electrode located on a gate insulating film which is located on the side wall of the drain layer facing the source layer and on the upper surface of the first semiconductor layer, the gate electrode extending from the side wall to the location of the source layer extending inwardly of the first semiconductor.

17. The field-effect transistor of claim 16, wherein the source layer is a second conductivity-type dopant diffusion layer formed in the first semiconductor layer in which second conductivity-type impurities are diffused from the upper surface of the first semiconductor layer; and
the drain layer is an epitaxial layer formed on the first semiconductor layer by epitaxial growth.

18. The field-effect transistor of claim 16, wherein
a first conductivity-type second semiconductor layer with a first conductivity-type dopant concentration higher than the dopant concentration of the first semiconductor layer is further provided on the lower surface of the first semiconductor layer, opposite to the gate electrode.

19. The field-effect transistor of claim 16, wherein
the gate electrode is formed of one of molybdenum, molybdenum silicide, and tungsten.

20. The field-effect transistor of claim 16, wherein
the gate electrode is formed of conductive silicon.
